(19) United States
(12) Patent Application Publication
(10) Pub. No.: US 2020/0256178 A1
(43) Pub. Date: Aug. 13, 2020

(54) Automated Reservoir Simulation

(71) Applicant: Landmark Graphics Corporation, Houston, TX (US)

(72) Inventors: Qinghua Wang, Houston, TX (US); Adithya Srinivasa, Houston, TX (US); Travis S. Ramsay, Hockley, TX (US); Steven P. Crockett, Sugarland, TX (US)

(73) Assignee: Landmark Graphics Corporation, Houston, TX (US)

(21) Appl. No.: 16/649,684

(22) PCT Filed: Nov. 15, 2017
(86) PCT No.: PCT/US2017/061806

§ 371 Date: Mar. 23, 2020

(51) Int. Cl. E21B 43/30; E21B 49/00; G06F 30/20; G06F 9/455

(52) U.S. Cl. CPC E21B 43/30; G06F 9/45558; G06F 30/20; E21B 49/003

(57) ABSTRACT

A method and system for automating a reservoir simulation. The method includes identifying a simulation parameter associated with a simulation resource to perform a computer-based reservoir simulation using reservoir data associated with a subterranean reservoir and configuring the simulation resource using a simulation engine to include the simulation parameter for performing the reservoir simulation with a reduced likelihood of simulation failure. The method also includes performing the reservoir simulation using the configured simulation resource and the reservoir data to generate reservoir simulation data and evaluate the reservoir.

### BACKGROUND

This section is intended to provide relevant background information to facilitate a better understanding of the various aspects of the described embodiments. Accordingly, it should be understood that these statements are to be read in this light and not as admissions of prior art.

A reservoir simulation is the process and associated techniques used to develop highly accurate dynamic 3D models of hydrocarbon reservoirs for use in predicting future production, placing wells, and evaluating reservoir management scenarios. The reservoir simulation model, built by an engineer, enables the quantitative interpretation of numerically modeled flow in a porous subsurface formation. Key techniques used in the process include integrated petrophysics and rock physics to determine the range of lithotypes and rock properties, geostatistical inversion to determine a set of plausible seismic-derived rock property models at sufficient vertical resolution and heterogeneity for flow simulation, stratigraphic grid transfer to accurately move seismic-derived data to the geologic model, and flow simulation for model validation and ranking to determine the model that best fits all the data.

Reservoir simulation, however, can be extremely computationally expensive, and complex simulations may rely upon a network of computer resources to complete the simulation within reasonable time frames. Misconfigured or inadequate computer resources can crash during a reservoir simulation, resulting in valuable time being wasted and computational resources being used on a failed reservoir simulation. Configuring the computer resources, however, may be beyond the expertise of some users, and as a result, a need exists for providing a cost-effective solution for the configuration of computer resources for reservoir simulations.

### BRIEF DESCRIPTION OF THE DRAWINGS

Embodiments are described with reference to the following figures. The same numbers are used throughout the figures to reference like features and components. The features depicted in the figures are not necessarily shown to scale. Certain features of the embodiments may be shown exaggerated in scale or in somewhat schematic form, and some details of elements may not be shown in the interest of clarity and conciseness.

FIG. 1 depicts an elevation view of a well system employing a computing system to evaluation a reservoir, according to one or more embodiments;

FIG. 2 depicts a block diagram view of an example computing system 200 that automates the configuration of the computing resources used to perform a reservoir simulation, according to one or more embodiments; and

FIG. 3 depicts a flowchart view of a method to automate the configuration of the simulation resources, according to one or more embodiments.

### DETAILED DESCRIPTION

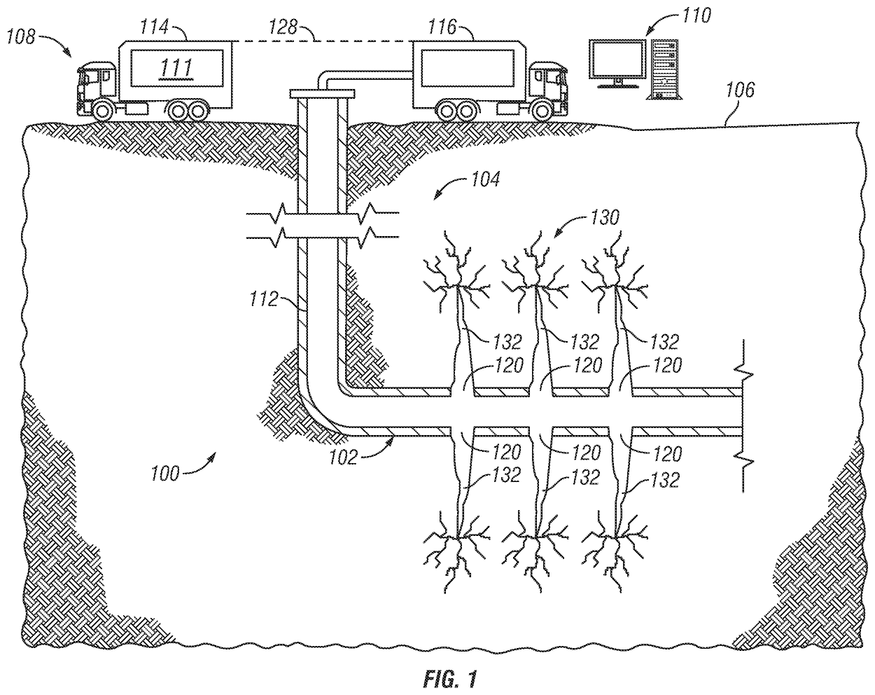

FIG. 1 is an elevation view of an example well system 100 and a computing subsystem 110. The example well system 100 includes a wellbore 102 in a subterranean region 104 beneath the ground surface 106. The example wellbore 102 shown in FIG. 1 includes a horizontal wellbore; however, a well system may include any combination of horizontal, vertical, slant, curved, or other wellbore orientations. The well system 100 can include one or more additional treatment wells, observation wells, or other types of wells.

The computing subsystem 110 can include one or more computing devices or systems located at the wellbore 102 or other locations. The computing subsystem 110 or any of its components can be located apart from the other components shown in FIG. 1. For example, the computing subsystem 110 can be located at a data processing center, a computing facility, or another suitable location. The well system 100 can include additional or different features, and the features of the well system can be arranged as shown in FIG. 1 or in another configuration.

The example subterranean region 104 may include a reservoir that contains hydrocarbon resources such as oil, natural gas, or others. For example, the subterranean region 104 may include all or part of a rock formation (e.g., shale, coal, sandstone, granite, or others) that contain natural gas. The subterranean region 104 may include naturally fractured rock or natural rock formations that are not fractured to any significant degree. The subterranean region 104 may include tight gas formations that include low permeability rock (e.g., shale, coal, or others).

The example well system 100 shown in FIG. 1 includes an injection system 108. The injection system 108 can be used to perform an injection treatment whereby fluid is injected into the subterranean region 104 through the wellbore 102. In some instances, the injection treatment fractures part of a rock formation or other materials in the subterranean region 104. In such examples, fracturing the rock may increase the surface area of the formation, which may increase the rate at which the formation conducts fluid resources to the wellbore 102.

The example injection system 108 can inject treatment fluid into the subterranean region 104 from the wellbore 102. For example, a fracture treatment can be applied at a single fluid injection location or at multiple fluid injection locations in a subterranean zone, and the fluid may be injected over a single time period or over multiple different time periods. In some instances, a fracture treatment can use multiple different fluid injection locations in a single wellbore, multiple fluid injection locations in multiple different wellbores, or any suitable combination. Moreover, the fracture treatment can inject fluid through any suitable type of wellbore such as, for example, vertical wellbores, slant wellbores, horizontal wellbores, curved wellbores, or combinations of these and others.

The example injection system 108 includes instrument trucks 114, pump trucks 116, and an injection treatment control subsystem 111. The example injection system 108 may include other features not shown in the figures. The injection system 108 may apply injection treatments that include, for example, a multi-stage fracturing treatment, a single-stage fracture treatment, a test treatment, a final fracture treatment, other types of fracture treatments, or a combination of these.

The pump trucks 116 can include mobile vehicles, immobile installations, skids, hoses, tubes, fluid tanks, fluid reservoirs, pumps, valves, mixers, or other types of structures and equipment. The example pump trucks 116 shown in FIG. 1 can supply treatment fluid or other materials for the injection treatment. The example pump trucks 116 can communicate treatment fluids into the wellbore 102 at or near the level of the ground surface 106. The treatment fluids can be communicated through the wellbore 102 from the ground surface 106 level by a conduit 112 installed in the wellbore 102. The conduit 112 may include casing cemented to the wall of the wellbore 102. In some implementations, all or a portion of the wellbore 102 may be left open, without casing. The conduit 112 may include a working string, coiled tubing, sectioned pipe, or other types of conduit.

The instrument trucks 114 can include mobile vehicles, immobile installations, or other suitable structures. The example instrument trucks 114 shown in FIG. 1 include an injection treatment control subsystem 111 that controls or monitors the injection treatment applied by the injection system 108. The communication links 128 may allow the instrument trucks 114 to communicate with the pump trucks 116, or other equipment at the ground surface 106. Additional communication links may allow the instrument trucks 114 to communicate with sensors or data collection apparatus in the well system 100, remote systems, other well systems, equipment installed in the wellbore 102 or other devices and equipment. In some implementations, communication links allow the instrument trucks 114 to communicate with the computing subsystem 110 that can run simulations and provide simulation data. The well system 100 can include multiple uncoupled communication links or a network of coupled communication links. The communication links can include wired or wireless communications systems, or a combination thereof.

The injection system 108 may also include surface and down-hole sensors to measure pressure, rate, temperature or other parameters of treatment or production. For example, the injection system 108 may include pressure meters or other equipment that measure the pressure of fluids in the wellbore 102 at or near the ground surface 106 or at other locations. The injection system 108 may include pump controls or other types of controls for starting, stopping, increasing, decreasing or otherwise controlling pumping as well as controls for selecting or otherwise controlling fluids pumped during the injection treatment. The injection treatment control subsystem 111 may communicate with such equipment to monitor and control the injection treatment.

The injection system 108 may inject fluid into the formation above, at or below a fracture initiation pressure; above, at or below a fracture closure pressure; or at another fluid pressure. The example injection treatment control subsystem 111 shown in FIG. 1 controls operation of the injection system 108. The injection treatment control subsystem 111 may include data processing equipment, communication equipment, or other systems that control injection treatments applied to the subterranean region 104 through the wellbore 102. The injection treatment control subsystem 111 may be communicably linked to the computing subsystem 110 that can calculate, select, or optimize treatment parameters for initialization, propagation, or opening fractures in the subterranean region 104. The injection treatment control subsystem 111 may receive, generate or modify an injection treatment plan (e.g., a pumping schedule) that specifies properties of an injection treatment to be applied to the subterranean region 104.

In the example shown in FIG. 1, an injection treatment has fractured the subterranean region 104. FIG. 1 shows examples of dominant fractures 132 formed by fluid injection through perforations 120 along the wellbore 102. Generally, the fractures can include fractures of any type, number, length, shape, geometry or aperture. Fractures can extend in any direction or orientation, and they may be formed at multiple stages or intervals, at different times or simultaneously. The example dominant fractures 132 shown in FIG. 1 extend through natural fracture networks 130. Generally, fractures may extend through naturally fractured rock, regions of un-fractured rock, or both. The injected fracturing fluid can flow from the dominant fractures 132, into the rock matrix, into the natural fracture networks 130, or in other locations in the subterranean region 104. The injected fracturing fluid can, in some instances, dilate or propagate the natural fractures or other pre-existing fractures in the rock formation.

In some implementations, the computing subsystem 110 can simulate fluid flow in the well system 100. For example, the computing subsystem 110 can include flow models for simulating fluid flow in or between various locations of fluid flow in the well system, such as, for example, the wellbore 102, the perforations 120, the conduit 112 or components thereof, the dominant fractures 132, the natural fracture networks 130, the rock media in the subterranean region 104, or a combination of these and others. The flow models can model the flow of incompressible fluids (e.g., liquids), compressible fluids (e.g., gases), or a combination of multiple fluid phases. In some instances, the flow models can model flow in one, two, or three spatial dimensions. The flow models can include nonlinear systems of differential or partial differential equations. The computing subsystem 110 can use the flow models to predict, describe, or otherwise analyze the dynamic behavior of fluid in the well system 100. In some cases, the computing subsystem 110 can perform operations such as generating or discretizing governing flow equations or processing governing flow equations.

The computing subsystem 110 can perform simulations before, during, or after the injection treatment. In some implementations, the injection treatment control subsystem 111 controls the injection treatment based on simulations performed by the computing subsystem 110. For example, a pumping schedule or other aspects of a fracture treatment plan can be generated in advance based on simulations performed by the computing subsystem 110. As another example, the injection treatment control subsystem 111 can modify, update, or generate a fracture treatment plan based on simulations performed by the computing subsystem 110 in real time during the injection treatment.

In some cases, the simulations are based on data obtained from the well system 100, such as data obtained during seismic, drilling, completion, or stimulation operations. For example, pressure meters, flow monitors, microseismic equipment, tiltmeters, or other equipment can perform measurements before, during, or after an injection treatment; and the computing subsystem 110 can simulate fluid flow based on the measured data. In some cases, the injection treatment control subsystem 111 can select or modify (e.g., increase or decrease) fluid pressures, fluid densities, fluid compositions, and other control parameters based on data provided by the simulations. In some instances, data provided by the simulations can be displayed in real time during the injection treatment, for example, to an engineer or other operator of the well system 100.

Some of the techniques and operations described herein may be implemented by a one or more computing systems configured to provide the functionality described. In various instances, a computing system may include any of various types of devices, including, but not limited to, personal computer systems, desktop computers, laptops, notebooks, mainframe computer systems, handheld computers, workstations, tablets, application servers, computer clusters, storage devices, or any type of computing or electronic device.

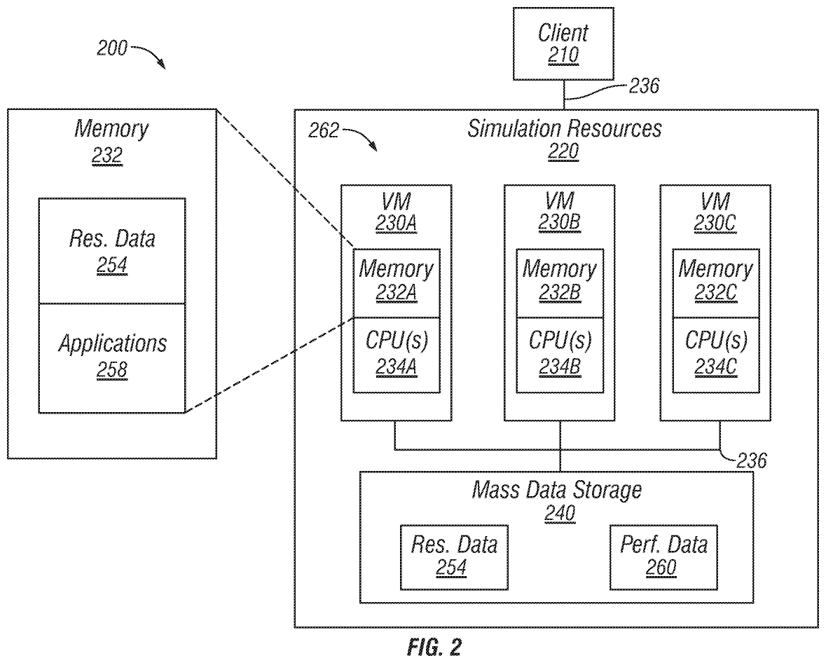

FIG. 2 is a block diagram view of an example computing system 200 that automates the configuration of the simulation resources 220 used to perform a computer-based reservoir simulation, according to one or more embodiments. The example computing system 200 can operate as the example computing subsystem 110 shown in FIG. 1, or it may operate in another manner. For example, the computing system 200 can be located at or near one or more wells of a well system or at a remote location apart from a well system. All or part of the computing system 200 may operate independently of a well system or well system components. The computing system 200 includes a client device 210 in communication with simulation resources 220 via communication links 236. The simulation resources 220 include one or more virtual machines 230A-C and data storage device 240. The simulations resources 220 (virtual machines 230A-C and/or data storage device 240) may operate in a public cloud over the Internet (e.g., Amazon Web Services or Microsoft Azure), in a private cloud over a local network, or in a hybrid cloud with some of the simulation resources 220 operating in a private cloud and other simulation resources 220 operating in a public cloud in communication with the private simulation resources 220.

Although three virtual machines 230A-C are shown in FIG. 2, it should be appreciated that any number of virtual machines/simulation resources may be available for automating the reservoir simulation. The virtual machines 230A-C may be emulated computer systems operating on a physical computer (not shown) to facilitate modular configuration of the computer resources available for running the reservoir simulation. The virtual machines 230A-C are in communication with the data storage device 240, and each virtual machine 230A-C includes a memory 232A-C and a processor 234A-C. The memory 232A-C can include, for example, a random access memory (RAM), a storage device (e.g., a writable read-only memory (ROM) or others), a hard disk, a solid state drive, or another type of storage medium.

The memory 232A-C can store instructions (e.g., computer code) associated with an operating system, computer applications, and other resources. The memory 232A-C can also store application data and data objects that can be interpreted by one or more applications or virtual machines running on the computing system 200. As shown in FIG. 2, the memory 232A-C includes reservoir data 254 and applications 258. The reservoir data 254 can include treatment data, geological data, fracture data, fluid data, or other types of data. The applications 258 can include flow models, fracture treatment simulation software, reservoir simulation software, or other types of applications. In some implementations, a memory of a computing device includes additional or different data, applications, models, or other information.

In some instances, the reservoir data 254 can include treatment data relating to injection treatment plans. For example the treatment data can indicate a pumping schedule, parameters of a previous injection treatment, parameters of a future injection treatment, or parameters of a proposed injection treatment. Such parameters may include information on flow rates, flow volumes, slurry concentrations, fluid compositions, injection locations, injection times, or other parameters.

In some embodiments, the reservoir data 254 includes geological data relating to geological properties of a subterranean region. For example, the geological data may include information on wellbores, completions, or information on other attributes of the subterranean region. In some cases, the geological data includes information on the lithology, fluid content, stress profile (e.g., stress anisotropy, maximum and minimum horizontal stresses), pressure profile, spatial extent, or other attributes of one or more rock formations in the subterranean zone. The geological data can include information collected from well logs, rock samples, outcroppings, microseismic imaging, or other data sources.

In some embodiments, the reservoir data 254 includes fracture data relating to fractures in the subterranean region. The fracture data may identify the locations, sizes, shapes, and other properties of fractures in a model of a subterranean zone. The fracture data can include information on natural fractures, hydraulically-induced fractures, or any other type of discontinuity in the subterranean region. The fracture data can include fracture planes calculated from microseismic data or other information. For each fracture plane, the fracture data can include information (e.g., strike angle, dip angle, etc.) identifying an orientation of the fracture, information identifying a shape (e.g., curvature, aperture, etc.) of the fracture, information identifying boundaries of the fracture, or any other suitable information.

In some embodiments, the reservoir data 254 includes fluid data relating to well system fluids. The fluid data may identify types of fluids, fluid properties, thermodynamic conditions, and other information related to well system fluids. The fluid data can include flow models for compressible or incompressible fluid flow. For example, the fluid data can include systems of governing equations (e.g., Navier-Stokes equations, advection-diffusion equations, continuity equations, etc.) that represent fluid flow generally or fluid flow under certain types of conditions. In some cases, the governing flow equations define a nonlinear system of equations. The fluid data can include data related to native fluids that naturally reside in a subterranean region, treatment fluids to be injected into the subterranean region, hydraulic fluids that operate well system tools, or other fluids that may or may not be related to a well system.

The applications 258 can include software applications, scripts, programs, functions, executables, or other modules that are interpreted or executed by the processor(s) 234A-C. For example, the applications 258 can include a fluid flow simulation module, a hydraulic fracture simulation module, a reservoir simulation module, or another other type of simulator. The applications 258 may include machine-readable instructions for performing a reservoir simulation as further described herein. The applications 258 may include machine-readable instructions for generating a user interface or a plot, for example, illustrating fluid flow or fluid properties. The applications 258 can receive input data such as treatment data, geological data, fracture data, fluid data, or other types of input data from the memory 232A-C, from another local source, or from one or more remote sources (e.g., via the communication link 236). The applications 258 can generate output data and store the output data in the memory 232A-C, in another local medium, or in one or more remote devices (e.g., by sending the output data via the communication link 236).

In some embodiments, the applications 258 may include a process, a program, an application, or another module that includes one or more threads. Here, the term “thread” is used broadly to refer to a computing sequence executed by computing hardware, and does not imply any particular hardware architecture. For instance, a thread can be a sequence of machine-readable instructions that can be independently accessed, executed, or otherwise managed by one or more processing units (e.g., the processor 234A-C). Multiple threads can be executed sequentially or concurrently by one or more processing units. The multiple threads may exchange data before, during, or after execution of the respective threads. Multiple threads can share resources such as memory. As an example, a process of the applications 258 can include two or more threads that share part or all of the memory 232A-C (e.g., the reservoir data 254). The shared memory can be accessed by the multiple threads and thus provide an efficient means for data passing, data synchronization, and communication among the multiple threads. In some instances, the multiple threads can establish a synchronous communication or an asynchronous communication among each other. For example, two communicating threads wait for each other to transfer a message in a synchronous communication scenario, while the sender may send a message to the receiver without waiting for the receiver to be ready in an asynchronous communication case. In some other implementations, the multiple threads can employ distributed memory, distributed shared memory, or another type of memory management mechanism for data passing between the threads.

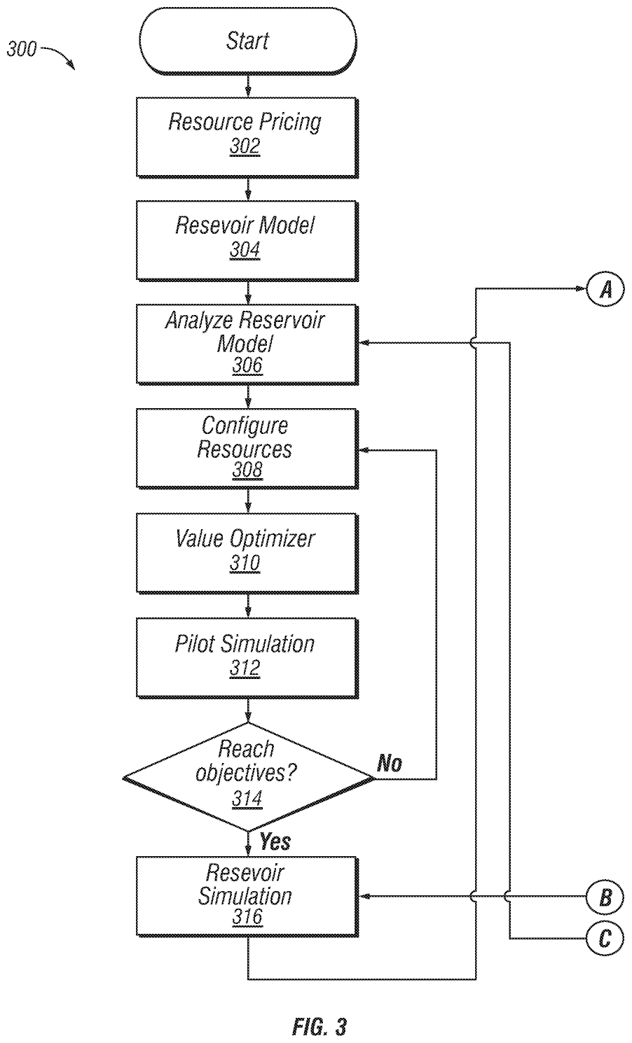

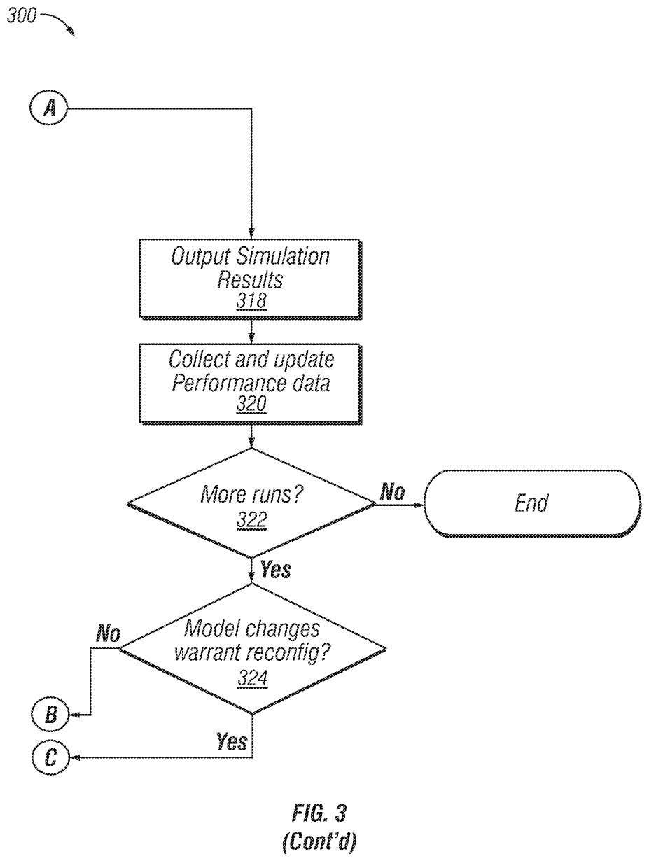

The processor(s) 234A-C can execute instructions, for example, to generate output data based on data inputs. For example, the processor(s) 234A-C can run the applications 258 by executing or interpreting the software, scripts, programs, functions, executables, or other modules contained in the applications 258. The processor 234A-C may perform one or more of the operations related to FIGS. 3-27. The input data received by the processor 234A-C or the output data generated by the processor 234A-C can include any of the treatment data, the geological data, the fracture data, the fluid data, or any other data.

The processor 234A-C can be a single-core processor or a multi-core processor. The single-core processor and the multi-core processor can both execute one or more threads sequentially or simultaneously. For instance, a single-core processor can run multiple threads in a time-division multiplexing manner or another manner and achieve multi-tasking. As an example, a single process of the applications 258 can include multiple threads. The multiple threads can be scheduled and executed on a single-core processor. On the other hand, a multi-core processor (e.g., a dual-core, quad-core, octa-core processor, etc.) can use some or all of its processing units (cores) to run multiple threads simultaneously. For example, each processing unit may execute a single thread independently and in parallel with each other. In some instances, the multiple processing units may have the same or different processing powers. The multiple threads can be dynamically allocated to the multiple processing units, for example, based on the computational loads of the threads, the processing powers of the processing units, or another factor. The multi-core processor may appropriately allocate the multiple threads to multiple processing units to optimize parallel computing and increase overall speed of a multiple-thread process.

The data storage device 240 may include internal storage devices, external storage devices, storage area network devices, etc. The data storage device 240 may provide data storage shared among the virtual machines 230A-C to access the reservoir data 254 as well as performance data 260. As further described herein, the performance data 260 can include a memory footprint of the simulation resources 220, simulation runtime, reservoir model information, and other suitable information obtained from completed reservoir simulations. A simulation engine 262, which may be one of the virtual machines 230A-C, may analyze the reservoir data 254 and compare the reservoir model information with the performance data 260 to configure the simulation resources 220 as further described herein. The client device 210 may also be in communication with the data storage device 240 to stage, setup, or configure the reservoir data 254 for running the reservoir simulation.

The simulation resources 220 may be used to automate the reservoir simulation with various objectives such as providing a reduced cost of operating the simulation resources 220 and a simplified user experience. Simplifying the user experience can be accomplished by automating the configuration of the simulation resources 220, which reduces the risk of the simulation failure due to resource constraints during the reservoir simulation and removes the user from considering the configuration of the simulation resources.

As an example of automating the reservoir simulation, FIG. 3 shows a flowchart of a reservoir simulation method 300, in accordance with one or more embodiments. At block 302, the pricing for various simulation resources can be input to optimize the configuration of the simulation resources 220 for reduce the cost of the simulation to the operator. An objective of maximum value return or reducing operating costs of the simulation resources depends on various factors and pricing models, including but not limited to the price per processor or core, the type of processor (CPU or GPU), the price for memory, the price for data storage, the price for simulation runtime, and the price for the geographical location of the simulation resources. The cost of a reservoir simulation may depend on the number of processors, the types of processors, the amount of memory, the amount of data storage, the simulation runtime, or communication bandwidth used. An objective of the automated simulation may be to reduce the cost of the reservoir simulation as further described herein.

At block 304, the simulation operator may use the client device 210 to input and configure the reservoir data 254 on the data storage device 240. The simulation operator may provide any relevant reservoir data 254 for performing the reservoir simulation, including but not limited to grid data, rock and fluid property data, initialization data, well data, surface network data, and control data. For example, the simulation operator may transfer any well logs to the data storage device 240 and input any other reservoir data including but not limited the rock and fluid property data. As further described herein, the simulation operator may adjust the reservoir data 254 to change the reservoir model used for subsequent simulations.

At block 306, the simulation engine 262 may analyze the reservoir data 254 and the performance data 260 to identify the minimum number of simulation resources 220 necessary to perform the reservoir simulation to satisfy various simulation objectives, including runtime and cost of the reservoir simulation. For example, the simulation engine 262 may reduce the reservoir data 254 to a reservoir signature and compare the reservoir signature with the performance data 260 to identify various simulation resource parameters, including but not limited to a network parameter, a data storage parameter, a processor parameter, and a memory parameter. The performance data 260 stores the relationship between performance metrics or parameters of previously completed reservoir simulations and their respective reservoir signatures obtained from the reservoir data. The performance data 260 can be continually updated with regression models of the performance parameters and the reservoir signatures from completed simulations. The simulation engine 262 may use pattern recognition to identify the simulation resources 220 from suitable matches between the current reservoir signature of the reservoir data 254 and the reservoir signatures from previously completed simulations. The simulation engine 262 may apply regression models to the reservoir data 254 and the performance data 260 to identify the number simulation resources 220 necessary to perform the reservoir simulation.

The simulation engine 262 also identifies various simulation parameters used to configure the simulation resources 220 and perform the simulation based on the performance data 260 with a reduced likelihood of simulation failure. The simulation engine 262 may identify the simulation parameters using the pattern recognition of the reservoir signatures and the performance data 260 of past simulation runs. The network parameter may include any one or combination of a minimum amount of network bandwidth needed to communicate among the simulation resources 220 enabled for the simulation, the type of communication links 236 (e.g., Ethernet, wireless, fiber optic, etc.) used by the simulation resources 220 to communicate amongst each other, and other suitable parameters related to network communications. The data storage parameter may include a minimum amount of data storage needed to perform the reservoir simulation, the transfer rate of the data storage, the type of data storage devices (e.g., external, internal, solid state drive, hard disk, tape drive, network storage, etc.), and other suitable parameters related to data storage. The processor parameter may include a minimum number of processors, cores, threads, the minimum amount of cache on each processor, type of processor (e.g., GPU, CPU), and other suitable parameters related to a processor needed to run the simulation. The memory parameter may include a minimum amount of memory, the memory transfer rate, the number of memory cards, and other suitable memory parameters for running the reservoir simulation on the simulation resources 220. These simulation parameters are merely exemplary, and various other simulation parameters may be used to automate the configuration of simulation resources 220.

At block 308, the simulation engine 262 configures the simulation resources based on the identified simulation parameters. For example, the simulation engine 262 may enable the number of virtual machines 230A-230C and amount of data storage needed for the simulation. The simulation engine 262 may also enable the number of processors 234, the type of processors 234, the amount of memory 232, and the type of memory 232 available for each virtual machine 230A-C. The simulation engine 262 may enable the communication links used to provide the minimum amount of network bandwidth for the simulation resources to communicate during the simulation.

At block 310, the simulation engine 262 may adjust the configuration of the simulation resources 220 based on considerations of the simulation cost versus simulation performance. For the optimal cost of the reservoir simulation, the simulation engine 262 may select cost effective simulation resources 220 based on the pricing parameters obtained at block 302 to achieve a suitable simulation runtime. The simulation operator may adjust or remove the cost objective of the simulation to allow for increased performance of the reservoir simulation to adjust the runtime. For example, the simulation operator may be more time bound than budget bound allowing the simulation resources 220 to be configured in such a way that the shortest runtime for the simulation is reached. Under a performance-based objective without any cost constraints, the simulation engine 262 may select the performance oriented simulation resources 220 available to reduce the runtime of the simulation without considering the cost of the simulation.

At block 312, the simulation resources 262 may perform a pilot run of the simulation to test whether the resources 220 configured can satisfy one or more objectives of the simulation. The objectives may include completing the simulation within the estimated runtime, meeting a cost objective of the simulation, meeting a performance objective of the simulation, identifying whether the resources 220 are likely to complete the simulation without any failures or errors, and any other suitable objective or condition associated with the simulation. The pilot run may be performed for a portion of the simulation (e.g., 5, 10, or 15%) to test the configured resources 220 for one or more objectives set for the simulation. The pilot run may be an optional step for the automated reservoir simulation.

At block 314, the simulation engine 262 checks whether the configuration of the resources 220 can meet the objectives set for the simulation. The simulation operator may input one or more objectives for the simulation from the client device 210. The simulation engine 262 may also use pre-programmed objectives, the operator defined objectives, or a combination thereof to determine whether the configuration of the simulation resources 220 satisfies the objectives. The simulation engine 262 may compare the objectives of the current simulation with the objectives set for previously completed simulations contained in the performance data 260 to determine whether the objectives are satisfied. In the case where a pilot run has been performed, the simulation engine 262 may analyze the pilot run to determine whether the objectives are satisfied. For example, the simulation engine 262 may determine that to complete 20% of the simulation during the pilot run the simulation exceeded the portion of the runtime. If the objectives are not reached, the simulation engine may return to block 308 to reconfigure the simulation resources 220. Otherwise, if some or all of the objectives are reached, the simulation engine 220 may proceed to block 316 to perform the reservoir simulation. The simulation operator may also override the objective check at block 314 to proceed with the reservoir simulation regardless of whether any objectives are reached.

At block 316, the configured simulation resources 220 are enabled to perform the reservoir simulation to evaluate a subterranean formation. As previously discussed, the reservoir data 254 collected from a well system is used by the simulation resources 220 to simulate fluid flow in the well system. Flow models of the reservoir can simulate the fluid injections, fluid recovery, fracturing operations, stimulation operations, etc. The reservoir simulation may model fluid flow for one or multiple reservoirs and model the reservoirs, wells, branched wells, and surface and subsurface facilities as a single fluid model to validate, plan, and optimize the development of the reservoir from planning the wells to producing the formation fluids, including hydrocarbon fluids, from the reservoir.

At block 318, the client device 210 may provide a user interface for the simulation operator to view and analyze the simulation results. The user interface may include an input device and an output device for the operator to evaluate the simulation results. The simulation operator may evaluate the production environment using the simulation results to validate, plan, and optimize the development of the reservoir.

At block 320, the simulation engine 262 may collect, analyze, and update the performance data 260 based on the performance of the configured resources 220 to run the reservoir simulation. The performance parameters may include the cost of the simulation, the runtime of the simulation, the results for each objective of the simulation, the configuration of the simulation resources 220, the reservoir signature of the reservoir data 254, and other suitable performance parameters associated with the simulation. The performance data 260 may be used in subsequent automations to select the appropriate configuration of the simulation resources 220 for future executions of simulation tasks.

At block 322, the simulation operator may decide whether other simulations are necessary to evaluate different models of the reservoir. In the situation where there are more simulations to run, the simulation operator may adjust or modify the reservoir model to evaluate the reservoir under different conditions, such as different rock types, fluid volumes, formation porosities, pressures, temperatures, etc. At block 324, the simulation engine 262 may determine whether any change to the reservoir data 254 warrants reconfiguration of the simulation resources at block 306 and if so proceed to reconfigure the simulation resources 220. The simulation engine 262 may determine the reservoir signature of the updated reservoir data and determine whether the simulation parameters would need to be updated as well based on the updated reservoir signature. If any change to the reservoir data 254 does not warrant a reconfiguration, the simulation engine 262 may initiate the reservoir simulation under the existing resource configuration at block 316, and the automated simulation may continue from block 316 as set forth above. In the situation where there are no more simulations to perform, the simulation operator may review the reservoir simulation data to evaluate reservoir including but not limited to evaluating the fluid flow in the well system, the injection treatment, or the recovery of hydrocarbon fluids from the well system.

It should be appreciated that the system and methods described herein provide a solution necessarily rooted in the software and simulation resources used to perform reservoir simulations. Configuring the resources to meet simulation objectives, including cost objectives or runtime objectives, can be excessively time consuming and may result in simulation failures without an automated process that integrates with past performance data of simulation resource configurations. The methods and system described herein automates the configuration of the simulation resources to avoid simulation failures and meet the objectives of the simulation operator or the pre-programmed objectives of a simulation engine.

In addition to the embodiments described above, many examples of specific combinations are within the scope of the disclosure, some of which are detailed below:

### Example 1

A method, comprising:
identifying a simulation parameter associated with a simulation resource to perform a computer-based reservoir simulation using reservoir data associated with a subterranean reservoir;
configuring the simulation resource using a simulation engine to include the simulation parameter for performing the reservoir simulation with a reduced likelihood of simulation failure; and
performing the reservoir simulation using the configured simulation resource and the reservoir data to generate reservoir simulation data and evaluate the reservoir.

### Example 2

The method of example 1, wherein identifying the simulation parameter comprises identifying an amount of memory used by the simulation resource necessary for running the reservoir simulation.

### Example 3

The method of example 1, wherein the simulation resource comprises a virtual machine comprising a processor and a memory.

### Example 4

The method of example 1, wherein configuring the simulation resource comprises selecting a network parameter, a data storage parameter, a processor parameter, and a memory parameter for the simulation resource necessary to run the computer-based reservoir simulation.

### Example 5

The method of example 1, wherein identifying the simulation parameter comprises identifying a minimum number of simulation resources necessary to perform the reservoir simulation to satisfy an objective of the reservoir simulation.

### Example 6

The method of example 1, further comprising identifying performance parameters of the completed reservoir simulation using a regression model of a reservoir signature from completed simulations for configuring the simulation resource for a subsequent reservoir simulation.

### Example 7

The method of example 1, wherein identifying the simulation parameter comprises reducing the reservoir data to a reservoir signature and comparing the reservoir signature with performance data obtained from previously completed reservoir simulations.

### Example 8

The method of example 1, wherein identifying the simulation parameter comprises using pattern recognition to identify a simulation parameter from a reservoir signature from a completed reservoir simulation matched with a reservoir signature of the reservoir data.

### Example 9

The method of example 1, further comprising configuring the simulation resource using the simulation engine to minimize the cost to perform the reservoir simulation using the simulation resource.

### Example 10

The method of example 1, further comprising performing a pilot simulation with the identified simulation parameter by comparing performance data of the pilot simulation with an objective of the reservoir simulation to optimize the configuration of the simulation resource.

### Example 11

A system, comprising:
a simulation resource operable to perform a computer-based reservoir simulation and evaluate the reservoir; and
a simulation engine operable to:
   identify a simulation parameter associated with the simulation resource to perform the reservoir simulation using reservoir data associated with a subterranean reservoir; and
   configure the simulation resource to include the simulation parameter and to perform the reservoir simulation with a reduced likelihood of simulation failure.

### Example 12

The system of example 11, wherein the simulation resource and the simulation engine each comprises a virtual machine comprising a processor and a memory.

### Example 13

The system of example 11, wherein the simulation engine is further operable to identify the simulation parameter comprising any one or combination of a network parameter, a data storage parameter, a processor parameter, and a memory parameter for the simulation resource necessary to run the reservoir simulation.

### Example 14

The system of example 11, wherein the simulation engine is further operable to identify an amount of memory used by the simulation resource necessary for running the reservoir simulation.

### Example 15

The system of example 11, wherein the simulation engine is further operable to configure the simulation resource to satisfy an objective of the reservoir simulation.

### Example 16

The system of example 11, wherein the simulation engine is further operable to identify a performance parameter of the completed reservoir simulation for configuring the simulation resource for a subsequent reservoir simulation.

### Example 17

The system of example 11, wherein the simulation engine is further operable to identify the simulation resource sufficient for running the reservoir simulation based on performance data of a previously completed reservoir simulation.

### Example 18

The system of example 11, wherein the simulation engine is further operable to determine a runtime of the reservoir simulation on the simulation resource using the reservoir data.

### Example 19

The system of example 11, wherein the simulation engine is further operable to configure the simulation resource by adjusting the simulation parameter to minimize the cost to perform the reservoir simulation using the simulation resource.

### Example 20

The system of example 11, wherein the simulation engine is further operable to perform a pilot simulation with the simulation resource by comparing performance data of the pilot simulation with an objective of the reservoir simulation to optimize the configuration of the simulation resource.

This discussion is directed to various embodiments of the present disclosure. The drawing figures are not necessarily to scale. Certain features of the embodiments may be shown exaggerated in scale or in somewhat schematic form and some details of conventional elements may not be shown in the interest of clarity and conciseness. Although one or more of these embodiments may be preferred, the embodiments disclosed should not be interpreted, or otherwise used, as limiting the scope of the disclosure, including the claims. It is to be fully recognized that the different teachings of the embodiments discussed may be employed separately or in any suitable combination to produce desired results. In addition, one skilled in the art will understand that the description has broad application, and the discussion of any embodiment is meant only to be exemplary of that embodiment, and not intended to suggest that the scope of the disclosure, including the claims, is limited to that embodiment.

Certain terms are used throughout the description and claims to refer to particular features or components. As one skilled in the art will appreciate, different persons may refer to the same feature or component by different names. This document does not intend to distinguish between components or features that differ in name but not function, unless specifically stated. In the discussion and in the claims, the terms “including” and “comprising” are used in an open-ended fashion, and thus should be interpreted to mean “including, but not limited to . . . .” Also, the term “couple” or “couples” is intended to mean either an indirect or direct connection. In addition, the terms “axial” and “axially” generally mean along or parallel to a central axis (e.g., central axis of a body or a port), while the terms “radial” and “radially” generally mean perpendicular to the central axis. The use of “top,” “bottom,” “above,” “below,” and variations of these terms is made for convenience, but does not require any particular orientation of the components.

Reference throughout this specification to “one embodiment,” “an embodiment,” or similar language means that a particular feature, structure, or characteristic described in connection with the embodiment may be included in at least one embodiment of the present disclosure. Thus, appearances of the phrases “in one embodiment,” “in an embodiment,” and similar language throughout this specification may, but do not necessarily, all refer to the same embodiment.

Although the present invention has been described with respect to specific details, it is not intended that such details should be regarded as limitations on the scope of the invention, except to the extent that they are included in the accompanying claims.

What is claimed is:

1. A method, comprising:
identifying a simulation parameter associated with a simulation resource to perform a computer-based reservoir simulation using reservoir data associated with a subterranean reservoir;
configuring the simulation resource using a simulation engine to include the simulation parameter for performing the reservoir simulation with a reduced likelihood of simulation failure; and
performing the reservoir simulation using the configured simulation resource and the reservoir data to generate reservoir simulation data and evaluate the reservoir.

2. The method of claim 1, wherein identifying the simulation parameter comprises identifying an amount of memory used by the simulation resource necessary for running the reservoir simulation.

3. The method of claim 1, wherein the simulation resource comprises a virtual machine comprising a processor and a memory.

4. The method of claim 1, wherein configuring the simulation resource comprises selecting a network parameter, a data storage parameter, a processor parameter, and a memory parameter for the simulation resource necessary to run the computer-based reservoir simulation.

5. The method of claim 1, wherein identifying the simulation parameter comprises identifying a minimum number of simulation resources necessary to perform the reservoir simulation to satisfy an objective of the reservoir simulation.

6. The method of claim 1, further comprising identifying performance parameters of the completed reservoir simulation using a regression model of a reservoir signature from completed simulations for configuring the simulation resource for a subsequent reservoir simulation.

7. The method of claim 1, wherein identifying the simulation parameter comprises reducing the reservoir data to a reservoir signature and comparing the reservoir signature with performance data obtained from previously completed reservoir simulations.

8. The method of claim 1, wherein identifying the simulation parameter comprises using pattern recognition to identify a simulation parameter from a reservoir signature from a completed reservoir simulation matched with a reservoir signature of the reservoir data.

9. The method of claim 1, further comprising configuring the simulation resource using the simulation engine to minimize the cost to perform the reservoir simulation using the simulation resource.

10. The method of claim 1, further comprising performing a pilot simulation with the identified simulation parameter by comparing performance data of the pilot simulation with an objective of the reservoir simulation to optimize the configuration of the simulation resource.

11. A system, comprising:
a simulation resource operable to perform a computer-based reservoir simulation and evaluate the reservoir; and
a simulation engine operable to:
identify a simulation parameter associated with the simulation resource to perform the reservoir simulation using reservoir data associated with a subterranean reservoir; and
configure the simulation resource to include the simulation parameter and to perform the reservoir simulation with a reduced likelihood of simulation failure.

12. The system of claim 11, wherein the simulation resource and the simulation engine each comprises a virtual machine comprising a processor and a memory.

13. The system of claim 11, wherein the simulation engine is further operable to identify the simulation parameter comprising any one or combination of a network parameter, a data storage parameter, a processor parameter, and a memory parameter for the simulation resource necessary to run the reservoir simulation.

14. The system of claim 11, wherein the simulation engine is further operable to identify an amount of memory used by the simulation resource necessary for running the reservoir simulation.

15. The system of claim 11, wherein the simulation engine is further operable to configure the simulation resource to satisfy an objective of the reservoir simulation.

16. The system of claim 11, wherein the simulation engine is further operable to identify a performance parameter of the completed reservoir simulation for configuring the simulation resource for a subsequent reservoir simulation.

17. The system of claim 11, wherein the simulation engine is further operable to identify the simulation resource sufficient for running the reservoir simulation based on performance data of a previously completed reservoir simulation.

18. The system of claim 11, wherein the simulation engine is further operable to determine a runtime of the reservoir simulation on the simulation resource using the reservoir data.

19. The system of claim 11, wherein the simulation engine is further operable to configure the simulation resource by adjusting the simulation parameter to minimize the cost to perform the reservoir simulation using the simulation resource.

20. The system of claim 11, wherein the simulation engine is further operable to perform a pilot simulation with the simulation resource by comparing performance data of the pilot simulation with an objective of the reservoir simulation to optimize the configuration of the simulation resource.
